(19) United States
(12) Patent Application Publication
(10) Pub. No.: US 2009/0277493 A1
(43) Pub. Date: Nov. 12, 2009

(54) CONCENTRATOR PHOTOVOLTAIC DEVICE, PV CONCENTRATOR MODULE FORMED THEREFROM AND PRODUCTION PROCESS THEREFOR

(75) Inventor: Erich W. Merkle, Munchen (DE)

Correspondence Address: FURR LAW FIRM, 2622 DEBOLT ROAD, UTICA, OH, 43080, US

(73) Assignee: SOLARTEC AG, München (DE)

(21) Appl. No.: 11/915,855

(22) PCT Filed: May 10, 2006
(86) PCT No.: PCT/DE2006/000804

§ 371 Date: Nov. 29, 2007

(30) Foreign Application Priority Data
Jun. 3, 2005 (DE) 10 2005 025 687.2
Jul. 15, 2005 (DE) 10 2005 033 272.2

(51) Int. Cl. H01L 31/052; H01L 31/00; H01L 31/18

(52) U.S. Cl. 136/246; 136/256; 438/73; 257/E21.158

(57) ABSTRACT

The invention relates to a photovoltaic device (20) for directly converting solar energy into electrical energy, comprising a solar cell (5) having a smaller surface area than a light entering surface (1) of the photovoltaic device (20), an optical unit (2) for concentrating the solar radiation (3) passing through to the light entrance surface (1) on a given area (22) defined by the smaller surface of the solar cell (5), positioned spaced apart from the light entering surface (1) and having a smaller surface in comparison to the light entering surface (1), and a transparent carrier body (6, 30) on which the solar cell (5) is arranged, For a simpler and cost-effective fabrication of the unit, it is proposed, that the carrier body is a transparent light exiting body (6, 30) through which the concentrated solar radiation (3) can pass and in that the solar cell (5) is arranged on a side of the light exiting body (6, 30) which is turned away from the light entering surface (1) and/or from the optical unit (2). Additionally, a PV concentration module (24) made up of multiple such photovoltaic devices as well as a cost-effective manufacturing process are proposed.

The invention relates to a photovoltaic device in accordance with the preamble of the attached claim 1 as it is known from the article A. W. Bett. et Al.: FLATCON AND FLASHCON CONCEPTS FOR HIGH CONCENTRATION PV, Proc. 19th European Photovoltaic Solar Energy Conference and Exhibition, Paris, France, 2004, page 2488. Particularly, the invention relates to a photovoltaic module (PV module) for the direct conversion of light into electrical energy, wherein the incident light is concentrated before arriving on a solar cell (PV concentrator module). The invention also relates to a photovoltaic apparatus in the form of a PV concentrator module made up of multiple photovoltaic devices. The invention relates finally to a method for producing such an apparatus.

In the field of the utilisation of solar energy, it has been well known for approx. 50 years, that solar energy is convertible into electricity by using silicon. Most currently used solar cells are made of mono- or multi-crystalline silicon. These solar cells have a relatively low power output as they convert only a limited spectrum of the incident radiation into electricity. In recent years great success has been achieved in essentially enhancing efficiency to a conversion rate of more than 36% of the solar radiation by using high efficiency PV cells made of high quality semi-conductor compounds (III-IV semi-conductor material) e.g. gallium arsenide (GaAs).

Such cells based on semi-conductor material can be formed step-like as tandem or triple-junction cells and, therefore, use a broader frequency spectrum of light.

It is, however, very cost-intensive to produce large surfaces of the cells. It has, therefore, been decided to concentrate the incident sunlight on a very small surface e.g. less than 1 mm². A solar cell is then only needed for this small surface. In this way less than 1% of the material is needed than would be for the entire surface. Due to this concentration it is now possible to benefit from a high light efficiency of currently more than 36% provided by high-efficiency PV cells. Since only the connection of several solar units allows an economical utilisation of such a PV system, these are ideally combined to form a PV concentrator module.

The article A. W. Bett et al. FLATCON AND FLASHCON CONCEPTS FOR HIGH CONCENTRATION PV, Proc. 19th European Photovoltaic Solar Energy Conference, and Exhibition, Paris, France, 2004, page 2488 as well as the article G. Siefer et al. ONE YEAR OUTDOOR EVALUATION OF A FLATCON CONCENTRATOR MODULE, Proc. 19th European Photovoltaic Solar Energy Conference and Exhibition, Paris, France, 2004, page 2078 describe the current state of the art related to such PV concentrator modules that forms the preamble of the attached claim 1.

For an electrical interconnection of the solar cells, contact electrodes are usually provided on the upper and the under side of the solar cells. It is necessary to connect these contact electrodes with each other and with further electrical components. In the above-mentioned state of the art the connection is made individually by means of contact bridges or contact loops made of an electrical conducting material or wire. This fabrication is relatively complex.

Furthermore, transportation of the arising heat is also necessary for a PV module and each tiny solar cell must be positioned accurately in the focus of the lens. The solar cells are embedded into a closed PV module for protection against external influences. According to the state of the art, solar cells are mounted on the inside of a lower glass plate within a transparent housing made up of several glass plates. This mounting approach does, however, have drawbacks concerning the necessary transportation of heat outwards and to possible contamination of the module interiors including the delicate solar cells. Due to the high complexity, systems with relatively large optics (typically more than 300 mm length) and, therefore, relatively large focal lengths have been used up until now. (For details see, e.g. the pages 462 and 463 in the chapter 11 of “Handbook of Photovoltaic science and engineering”, edited by Antonio Luque and Steven Hegedus, newly-printed in the year 2005). Unifying such systems to efficient assemblies (solar power plants) leads to a huge weight making high demands on the static of a tracker tracking the PV modules to the sunlight, e.g. in case of wind.

Despite the growth of photovoltaic generated currents the use of these well known concentrator systems has not become widespread as they are so complex.

In recent years, concentrator systems with small-area optics with partial concentration of more than 500-times of the sunlight have also been available. In this case, however, a very large number of cells are needed to provide an economical solar power plant. When using lenses with a dimension of 40×40 mm, approx. 250,000 solar cells (with 25% system efficiency) are needed for a solar installation providing 100 kW power. The additional costs incurred from the constructional problems of the wiring of so many tiny solar cells and of additional circuit components together with the accurate positioning and fixation of each cell in the focus outweigh the proposed costs saved. As yet, the problems with the conduction of high heat concentrations outwards, the protection of the sensitive solar cells against environmental influences, particularly against penetrating humidity and gases have not yet been solved, nor has the opportunity to test the solar cells before assembling the PV concentrator module.

The object of the invention is to design a photovoltaic unit according to the attached preamble of the attached claim 1 which uses the advantages of the PV concentrator technology in such a way as to solve the above-mentioned problems. Especially, there is the need to build a photovoltaic apparatus consisting of multiple such photovoltaic devices, particularly a PV concentrator module, in such a way as to allow large-scale production at a low cost, thus avoiding the above-mentioned drawbacks.

For solving the above-mentioned problems the invention provides a photovoltaic device with the features specified in claim 1. Advantageous embodiments are given in the dependent claims. A photovoltaic apparatus formed of multiple photovoltaic devices which is simple to manufacture as well as a cost-effective producing method are the subjects of the further independent claims.

Advantages of the present invention and/or their preferred embodiments are:
Due to the placement of the solar cells on the outside of the transparent reverse-side of a carrier body, the heat conduction and the protection of the solar cells can be improved.
Due to an automated placement and wiring of the large number of solar cells of a module as well as due to the thereby possible automated positioning of all solar cells of a module, the assembly can be substantially simplified.
Due to the simple testing possibility of the module before the final assembly, an early quality control with the possibility of exchanging defective solar cells or circuit components can be performed.
Applying a heat conducting plate on the outside of the module, enables an efficient conduction of heat to the environment.
On the reverse side of a transparent light exiting surface, a hermetic encapsulation of the solar cells as well as of the electrical contacts can be simply achieved.

In order to perform the represented tasks which are important for a cost-effective production of a PV concentrator module, one has given up the way used up to now for development that was characterized amongst others things, in that the solar cells are individually arranged inside the module, are individually contacted and are upwardly basically unprotected exposed to environmental influences.

This invention provides a focusing of the sunrays on the underside of a transparent light exiting body. The transparent material of the light exiting body can that way serve on the one hand as substrate for the solar cell (cells), on the other hand it can cover the sensitive light entering zone of the expensive solar cell (cells) against environmental influences. On the reverse side of the transparent light exiting body, which is preferably built for forming a transparent light exiting surface in the shape of a plate or of a disk, the solar cells can easily be reached for the purpose of electrical contacting and heat conduction. Three-dimensional as opposed to two-dimensional heat dissipation devices can be provided as known from high-efficiency electronic devices, like for example for ribbed structures.

In a preferred embodiment the light exiting body is assembled spaced apart from an optical (focusing) unit mounted on given areas for concentrating the light. A light entering surface together with the focusing unit and the light exiting body are then arranged spaced apart to each other, so that a large distance is available for the focusing and all light from a large surface can be focussed on the small solar cell surface by means of relatively plain and simple optics.

In another, however also very interesting embodiment, the carrier body has on one side the light entering surface and on the opposite side the light exiting surface with the solar cell. The unit can that way be simply constructed and can be handled individually as small light emitting diodes. The light entering surface of the carrier body which is designed from suitable transparent material usually as a solid body is formed accordingly for focusing the light on the solar cell mounted on the reverse side.

This embodiment of the photovoltaic unit can be made as individual cell, e.g. similar to a light emitting diode, having for instance a circular cross section. A number of these individual cells with mounted carrier body as focusing unit can then be assembled onto a plate to form a module.

If the cross section is not circular but rectangular or still better square, the total area can be better equipped.

The embodiment, in which only the carrier body is provided as focusing unit, can, however, be assembled to a module very simply in such a way that an individual carrier body carries several solar cells on the reverse side and is formed on the front side working as light entering surface for forming adequate optical units. The mounting of the solar cells can be simply automated, if these are arranged in a regular pattern, particularly in a square pattern. If the carrier body is inserted as rolling glass and the focusing pattern is inserted like an ornament in patterned glass by means of a patterned roller, the light entering surface with a pattern of many individual optical units can be manufactured very simply.

In both fundamental embodiments the solar cells are arranged at a light exiting surface of a transparent carrying body, so that the advantageous technologies for contacting the solar cells described below are equally applicable for both.

Alternatively, or additionally, to the mounting on the reverse side of the transparent light exiting surface, the solar cell (cells) is/are preferably embedded in a conducting plate or a conducting foil and electrically connected with this. Thus, conducting paths for all or a group of the solar cells can easily be produced in one step, instead of the complicated manufacturing by means of individual contacting.

To protect the cell from penetrating humidity and air the conducting plate should preferably be connected—for example laminated, and especially fully laminated—to the transparent light exiting surface.

As an alternative to the use of a conducting plate or conducting foil, the electrical connections and an insulating layer can be applied directly onto the transparent light exiting surface. For this purpose, the methods for forming integrated conducting paths as well as isolating intermediate areas known from electronics and semiconductor technology are applicable. Preferably the insulating layer is made by using a coating capable of flow. The insulating layer can also be used for embedding and/or for fixing the solar cells and/or of further circuit components.

Preferably the solar cells should be further connected on the underside with a heat conducting layer, which should provide the electrical contact as well as the transport of the heat impinging on the solar cell.

As in the state of the art, the optical unit positioned spaced apart can directly concentrate the radiation on the solar cell. Alternatively, the focusing or collecting unit can comprise the first optical unit positioned spaced apart from the transparent light exiting surface and an additional second optical unit close to the solar cell. A concentration can occur from the first optical unit onto a secondary lens, for example. This then continues to concentrate the incident light on the solar cell.

The first and/or the second optical unit can be made of the same material as one of the first transparent light entering surfaces assigned to the first optical unit and the second transparent light exiting surface assigned to the second optical unit. However, they can also be made of a different material and be mounted on the transparent light entering and light exiting body.

Since very small solar cells can be used for the invention described above, the high costs of multi-junction solar cells is irrelevant. With this invention, investment costs for concentrated solar systems for the production of electricity are much lower, and the area needed much smaller.

Embodiments of the invention are described in more detail below on the basis of the accompanying drawings:

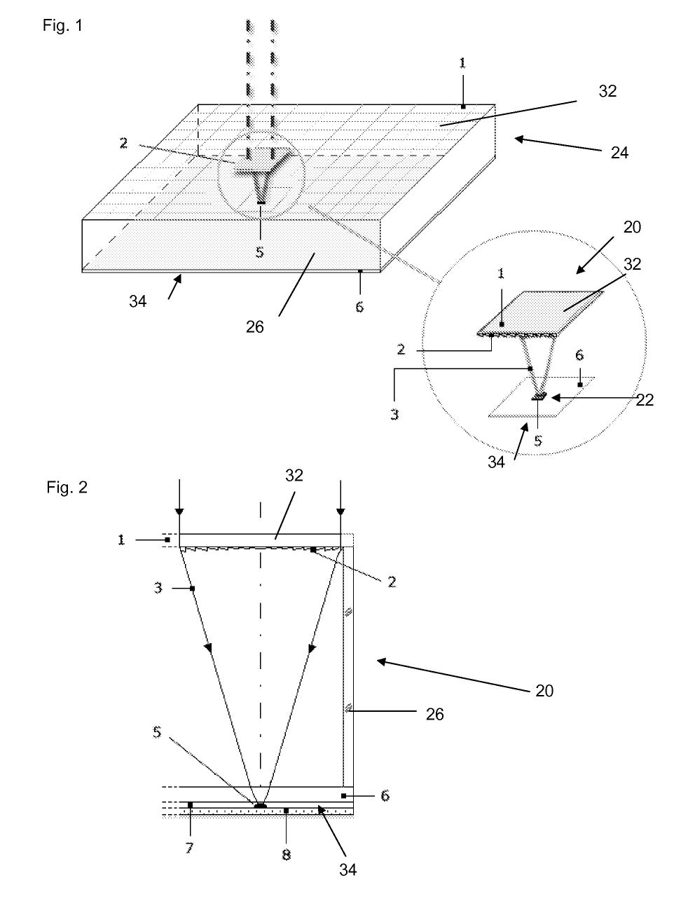

FIG. 1. is a perspective view of a photovoltaic apparatus in form of a PV concentrator module with multiple individual photovoltaic devices (also called concentrator unit) each directly converting sunlight concentrated on a small-area solar cell into electrical energy, as well as a schematic detail view of the common structure of a first embodiment of the photovoltaic units;

FIG. 2. is a cross-sectional view through a photovoltaic device usable in a first embodiment of the photovoltaic apparatus of FIG. 1 (with conducting plate and without secondary lens);

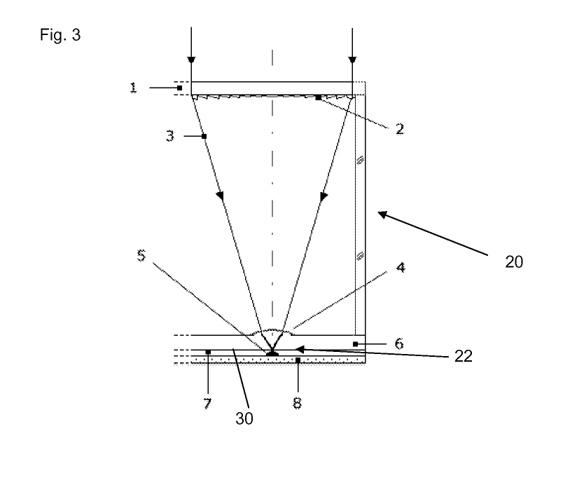

FIG. 3. is a cross-sectional view through a photovoltaic device usable in a second embodiment of the photovoltaic apparatus of FIG. 1 (with conducting plate and with secondary lens);

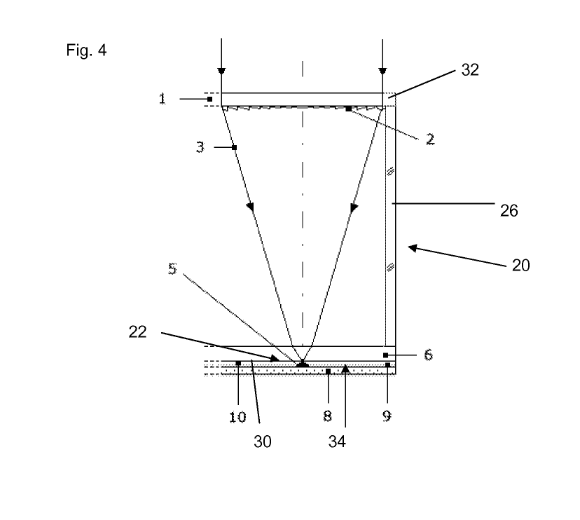

FIG. 4. is a cross-sectional view through a photovoltaic device usable in a third embodiment of the photovoltaic apparatus of FIG. 1 (with conducting paths and without secondary lens), and

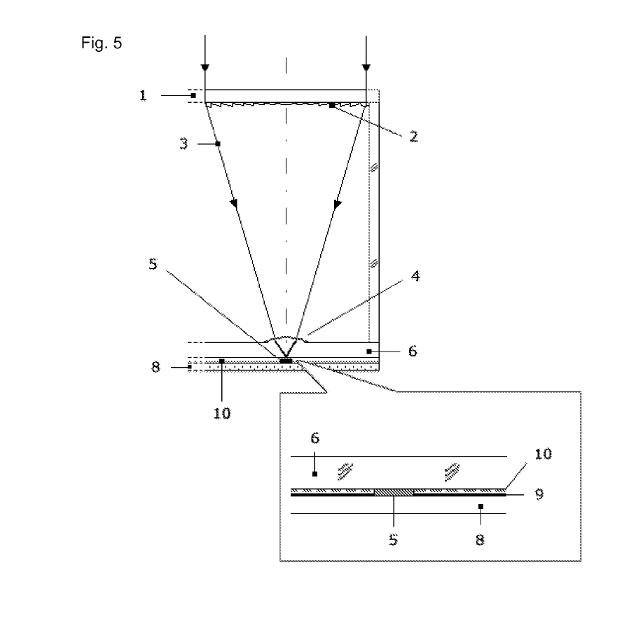

FIG. 5. is a cross-sectional view through a photovoltaic device usable in a forth embodiment of the photovoltaic apparatus of FIG. 1 (with conducting paths and with secondary lens);

FIG. 6. is a cross-sectional view along a vertical central plane through a photovoltaic device according to a fifth embodiment;

FIG. 7. is a bottom view of the photovoltaic device according to the fifth embodiment;

FIG. 8. is a lateral view of a photovoltaic device according to a sixth embodiment;

FIG. 9. is a bottom view of the photovoltaic device according to the sixth embodiment;

FIG. 10. is a top view of the photovoltaic device according to the sixth embodiment;

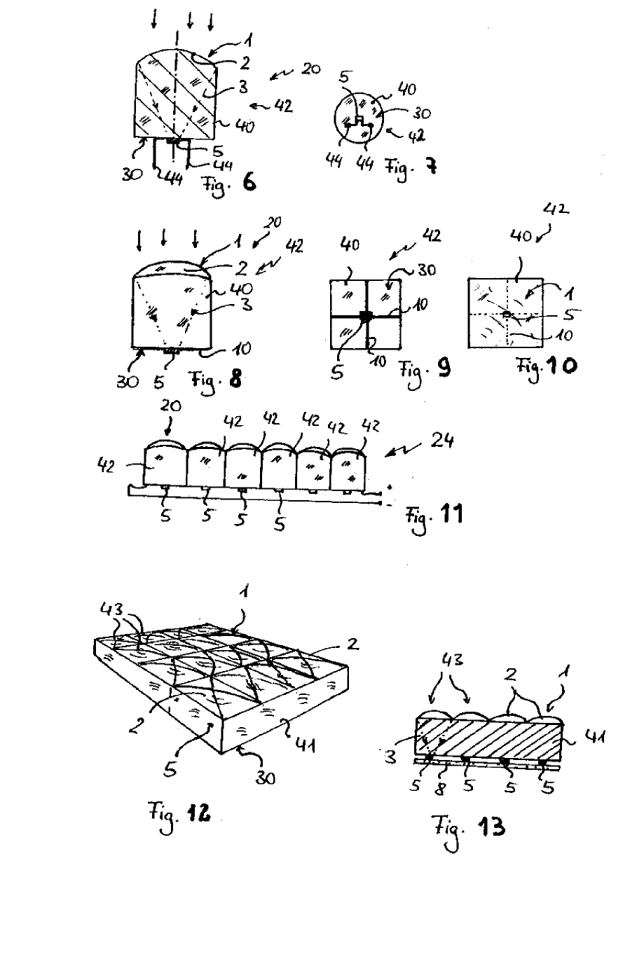

FIG. 11. is a cross-sectional view through a photovoltaic apparatus formed from several photovoltaic devices of the sixth embodiment;

FIG. 12. is a perspective view of a photovoltaic apparatus according to a seventh embodiment; and

FIG. 13. is a cross-sectional view through the photovoltaic apparatus according to the seventh embodiment.

For the following description of the preferred embodiments the same reference numbers are used for corresponding parts.

FIG. 1 shows a photovoltaic apparatus 24 in form of a PV concentrator module with multiple individual photovoltaic devices 20 in the form of individual concentrator units each with at least one micro solar cell 5. For a first embodiment of the photovoltaic device 20 as shown in FIG. 1 and FIG. 2 a high-productive and automated fabrication is made possible due to the use of conducting plates 7 or conducting foils for the common connection of the micro-solar cells 5 in the module, as well as for additional circuit components favourable for the flow of the electric current.

The application of the contacting paths and of the solar cells 5 can be carried out in such a way that they can easily be tested by the connection to a direct-current supply. Due to the construction principle the solar cells 5 light up, so that a simple visual or technically supported optical control can be effected. Furthermore, the electrical characteristics can be determined and compared with reference values. Any faulty individual solar cells 5 can be exchanged.

The critical positioning of the solar cells 5 is accurately predetermined in a conducting plate 7 or conducting foil. The entire printed conducting plate 7 can be accurately positioned relative to the focus points of the sunrays 3, which are concentrated by an optical unit 2, in a subsequent procedure.

By applying a heat conducting layer 8 (see FIG. 2) onto the outside 34 of a transparent housing 26 of the photovoltaic apparatus 24—namely on the outside of a light exiting plate 6 of the housing 26 forming the light exiting surface 30—heat is transported to the surroundings. The heat conductivity of the heat conducting layer 8 can be selectively changed by using especially conductive material and/or using different thickness of the material and also later by additional application of material layers.

In a second embodiment shown in FIG. 3, concentrated sunrays 3 are firstly directed onto a secondary lens 4, which then causes further concentration and directing of the rays onto the solar cell 5. The secondary lens 4 can be thereby made directly from a transparent light exiting surface 6 or consist of another material. The use of a secondary lens 4 has the advantage, that, on the one hand, higher concentrations of over 1000 suns are reached. This leads to an improvement in the degree of efficiency of certain multi-junction high-performance solar cells. On the other hand, a less exact tracking of the modules to the light source is needed if using a secondary lens 4, so that the requirements to be set on the tracker are reduced. The possible economies of this can exceed the costs of the additional secondary lenses 4. The increase in efficiency still leads to an additional effect.

In the third embodiment shown in FIG. 4 the electrical conducting paths 10 as well as the connections for the solar cell 5 and the further circuit components (not shown) are directly mounted on the underside/outside 34 of the transparent light exiting surface 6 instead of using a conducting plate 7. This can be done by means of screen printing, or other suitable processes. The solar cells 5 and further circuit and connection components are assembled, connected and tested (see above). After the coating of an (adhesive) insulating layer 9, the heat conducting layer 8 is assembled onto this and onto the underside of the solar cells 5. The heat conductivity of the heat conducting layer 8 can be selectively changed by using especially conductive material and/or different thicknesses of the material and also later by additional application of conductive material layers.

In the fourth embodiment shown in FIG. 5, the concentrated light rays 3 are initially directed onto a secondary lens 4 which then provides further concentration and directing of the rays onto the solar cell 5. The secondary lens 4 can be thereby formed entirely or partly by the transparent light exiting surface 30 forming the transparent light exiting plate 6 or can be made of another material. The advantages of the secondary lens 4 are the same as described above.

A huge advantage of this new technology is, that both the required area and the performance-related investments costs of mass production only amount to around approximately 50% of the costs of conventional flat panel systems of silicon. This results in substantially lower production costs of electricity. Since the generation of solar power occurs in sun-rich countries predominantly at peak load times (i.e. they run to capacity at the “hot” time of day in the air conditioning systems and production), electricity production costs can, for the first time, be realistically considered to be within the range achievable by conventional power plants.

As shown in the figures, the photovoltaic device 20 for the converting sunlight directly into electrical energy is built as a transparent unit. The photovoltaic device 20 concentrates the light radiation entering through a transparent light entering surface 1 by means of the optical unit 2 within a predetermined area 22. This predetermined area 22 is situated outside of the transparent unit and is turned away from the light entering surface 1. A solar cell 5 is positioned in the predetermined area. A heat conducting layer 8 is connected with the solar cell 5.

As shown in FIG. 1, a plurality of such photovoltaic devices 20 is combined in the photovoltaic apparatus 24. The photovoltaic apparatus 24 has a housing 26 in which the photovoltaic devices 20 are arranged and connected by means of a conducting plate 7. That way the photovoltaic apparatus 24 forms a PV concentrator module (PV means photovoltaic).

The contacts between the solar cells 5 of the individual photovoltaic devices 20 and possibly to further electrical circuit components which can be provided for controlling and converting are mounted directly onto the outside of the transparent light exiting plate 6 or on the conducting plate 7 or conducting foil.

In one embodiment the optical unit 2 is at least partly made of a transparent material particularly of silicone material which, for the entire photovoltaic apparatus 24, is coated in one procedure directly onto the front plate 32 of the housing 26, which forms the transparent light entering surface 1, and is impressed into the layer.

In an alternative embodiment, the optical unit 2 is worked out directly from the transparent light entering surface 1, for example by grinding and/or lapping, so that the transparent material of the optical unit forms one piece with the transparent material of the light entering surface 1.

A method for testing the photovoltaic device 20 and/or the entire photovoltaic apparatus 24 can be carried out by testing the connected solar cells 5 by means of applying voltage. Thereby, a test of the entire installed unit can also be carried out by applying voltage.

A continuous heat conducting layer 8 is connected with the reverse side of the micro solar cells 5 to form the heat conducting layer 8 which transports the heat from the solar cells 5.

An additional concentration of the radiation 3 concentrated by the optical unit 2 can be carried out by means of a secondary lens 4 (FIG. 5) directly formed from the transparent light exiting plate 6.

Alternatively, the additional concentration of the radiation 3 can be carried out by means of a secondary lens 4 (FIG. 6) mounted onto the transparent light exiting plate 6.

Instead of providing a conducting plate 7 or a conducting foil, the electrical contacting and connecting paths—more generally the conducting paths 10—can be mounted, as shown in FIG. 5, directly onto the outside of the transparent light exiting plate 6 as can the solar cells 5 and possible electrical circuit components (capacitive, inductive or in particular resistive components, controls, amplifiers, microchips or microprocessors). This can be done in different ways, as known from the field of electronics. Preferably, the conducting paths 10 are applied by means of screen printing technology. Alternatively, vaporization procedures or sputtering procedures or suchlike can be used. These procedures are carried out by means of masks which predetermine the course of the conducting paths. The procedures known from the semiconductor technology are also possible, wherein initially an entire conducting layer is applied to a transparent material, then a photosensitive material (which is selectively removed after the exposure) is applied, in order to remove the material from the unwanted areas of the conducting layer, while the remaining areas for conducting paths are protected by the remaining material.

According to one embodiment, an insulating layer 9 causing an electrical isolation and/or a reverberation of the arising thermal radiation is applied to the conducting paths 10.

The transparent light exiting plate 6 can be made as one layer or multilayered. It can comprise or be made up of, for instance, a glass plate. Additionally, further transparent layers can also be applied, for instance an isolating and closing layer of silicone or of another transparent material which can be applied in a fluid state. If the light exiting plate 6 comprises a glass plate, an additional concentration of the radiation 3 can be carried out by means of a secondary lens 4 which is directly produced from the reverse side of the glass.

Alternatively, the secondary lens 4 for additional concentration of the rays 4 can also be mounted onto the glass.

The first optical unit 2 can be made as described with the afore-mentioned state of the art, for example by means of Fresnel lenses made of glass at the front plate 32 forming the light entering surface 1.

In the fifth to seventh embodiment shown in the FIGS. 6 to 13, the light entering surface 1 and the light exiting surface 30 are made as the front and reverse side of an individual transparent carrier body 40, 41. The carrier body 40, 41 is built as a solid body of transparent material, typically glass. The optical unit (units) is (are) provided at the light entering surface 1 of the said carrier body 40, 41. The solar cell (cells) 5 is (are) provided at the light exiting surface 30 of the said carrier body 40, 41.

The optical units 2 and the contacting, embedding, cooling and mounting of the solar cells 5 can be manufactured as in the above-mentioned further embodiments.

In the fifth and sixth embodiments shown in the FIGS. 6 to 10, the individual photovoltaic units 20 are made as individual cells 42. Each solar cell 5 has its own carrier body 40 which serves as a focusing unit for concentrating the light occurring on the light entering surface 1 as well as on the much smaller surface of the solar cell 5.

In the fifth embodiment, the carrier body 40 has a circular cross section with a round upper surface (which works as a lens) and a flat underside. The underside can be mounted with contact pins 44 by which each of the individual cells 42 can be superimposed on a card (not shown). An arrangement made up of individual cells 42 can in that way be assembled to make a PV module.

In the sixth embodiment, the carrier body 40 of each individual cell 42 has a square base area. In this way, a plurality of the individual cells 42 can be more easily assembled to make a PV concentrator module 24, as shown in FIG. 11. Any suitable technique, like for example adhesion or simple insertion into an exterior framework (not shown) can be used for connecting the individual carrier bodies 40.

Having individual cells 42 for the arrangement, means these can also be tested later at any time by applying a voltage. The solar cells 5 then light up like light emitting diodes, only more weakly. If an individual solar cell does not light up, it can easily be replaced, even at a later stage.

In the seventh embodiment, several solar cells 5 are supported by a carrier body 41. The solar cells 5 are arranged (as described before for the other embodiments) in a pattern, here in a square alignment pattern with equal intervals. The light entering surface of the carrier body 41 is formed in a pattern corresponding to the optical units which focus the light occurring in the respective fields 43 onto the respective solar cell 5.

These optical units can be also made as described for the other embodiments. For all embodiments where a regular pattern of optical units has to be manufactured on a surface of a transparent plate, there is an additional possibility of manufacturing these in a rolling glass procedure. A roller provided with negative pattern (not shown) impresses the pattern directly into the glass mass during the glass manufacture. This manufacturing procedure is well-known in the manufacturing of patterned glass. In particular, the carrier body 41 of the seventh embodiment is manufactured in this way.

The seventh embodiment is particularly suitable for large industrial manufacturing of relatively cost-effective PV concentrator modules.

Further embodiments arise as a result of any combination of the individual features of the different embodiments.

### LIST OF REFERENCE SIGNS

1 transparent light entering surface
2 optical unit
3 rays through optical unit
4 secondary lens
5 solar cell
6 transparent light exiting plate (back plate)
7 conducting plate/foil
8 heat conducting layer
9 insulating layer
10 conducting paths
20 photovoltaic device
22 predetermined area (focus)
24 photovoltaic apparatus (PV concentrator module)
26 housing
30 transparent light exiting surface
32 front plate
34 outside
40 carrier body (individual cell)
41 carrier body (module)
42 individual cell
43 field
44 contact pins

1. A photovoltaic device (20) for directly converting solar energy into electrical energy, comprising:
a solar cell (5) having a smaller surface area than a light entering surface (1) of the photovoltaic device (20),
an optical unit (2) for concentrating the solar radiation (3) passing through to the light entrance surface (1) on a given area (22) defined by the smaller surface of the solar cell (5), positioned spaced apart from the light entering surface (1) and having a smaller surface in comparison to the light entering surface (1), and
a transparent carrier body (6, 30) on which the solar cell (5) is arranged,
characterized in that
the carrier body is a transparent light exiting body (6, 30) through which the concentrated solar radiation (3) can pass and
in that the solar cell (5) is arranged on a side of the light exiting body (6, 30) which is turned away from the light entering surface (1) and/or from the optical unit (2).

2. The photovoltaic device according to claim 1,
characterized in that
the light exiting body comprises a light exiting plate (6) of transparent material.

3. The photovoltaic device according to claim 2,
characterized in that
the solar cell (5) directly contacts the side (34) of the light exiting plate (6) which is turned away from the light entering surface (1).

4. The photovoltaic device according to claim 2,
characterized in that
a layer (9) of transparent material applied in a fluid state is inserted between the solar cell (5) and the side (34) of the light exiting plate (6) which is turned away from the light entering surface (1).

5. The photovoltaic device according to any of the preceding claims,
characterized in that
additionally to a first optical unit (2) assigned to the light entering surface (1) a second optical unit (4) assigned to the light exiting body (6) is provided for further concentrating of the solar radiation (3) in the given area (22).

6. The photovoltaic device according to any of the preceding claims,
characterized in that
the optical unit (2) or at least one of several optical units (2, 4) has a convex lens (4) made from the material of a transparent light entering plate (32) or of a transparent light exiting plate (6) or of the carrier body.

7. The photovoltaic device according to any of the preceding claims,
characterized in that
the optical unit (2) or at least one of the several optical units (2, 4) has a convex lens (4) applied on a transparent light entering plate (32) or on a transparent light exiting plate (6) or by application of material onto the carrier body.

8. The photovoltaic device according to the preamble of the claim 1 and in particular according to any of the preceding claims,
characterized in that
conducting paths (10) for contacting the solar cell (5) are directly applied onto the carrier body (6) by application of material, particularly by printing or by sputtering.

9. The photovoltaic device according to any of the preceding claims,
characterized in that
a heat conducting unit (8) for transporting heat is connected with the solar cell (5) on the side turned away from for the carrier body (6).

10. The photovoltaic device according to any of the preceding claims,
characterized in that
the carrier body comprises, in one piece, both the light entering surface having the optical unit and the light exiting surface with the solar cell arranged thereon.

11. The photovoltaic device according to claim 10,
characterized in that
the carrier body is built as a solid body of transparent material comprising the light entering surface formed correspondingly for establishing the optical unit on one side and carrying the smaller solar cell within the focus area of the optical unit on the opposite side.

12. The photovoltaic device according to claim 11,
characterized in that
it is made as a single cell of a carrier body for one solar cell as well as of said one solar cell arranged at the carrier body.

13. The photovoltaic device according to claim 12,
characterized in that
the carrier body has a circular, square or rectangular cross section when sectioned parallel to the light entering and light exiting surfaces.

14. A photovoltaic apparatus (24) comprising a plurality of photovoltaic devices (20) in accordance with any of the preceding claims.

15. The photovoltaic apparatus according to claim 14,
characterized in that
it is assembled as a module from several individual photovoltaic devices in accordance with any of the claims 1 to 13.

16. The photovoltaic apparatus according to claim 14,
characterized in that
at least the carrier body for several of the photovoltaic devices is formed as one piece and thus carries several of the solar cells.

17. The photovoltaic apparatus according to claim 16,
characterized in that
the common carrier body is designed as a solid body of transparent material carrying the solar cells on its light exiting surface in a regular pattern and comprising a surface made for building a corresponding pattern of optical units on the opposite side.

18. The photovoltaic apparatus according to claim 17,
characterized in that
the pattern of optical units is manufactured by rolling a carrying body made of glass with a corresponding patterned roller.

19. The photovoltaic apparatus according to any of the claims 14 to 18,
characterized in that
it is provided with a housing (26) whose transparent front plate (32) forms the light entering surfaces (1) of the photovoltaic devices (20) and whose transparent back plate (6) forms the common light exiting body of the photovoltaic devices (20).

20. The photovoltaic apparatus according to any of the claims 14 to 18,
characterized in that
it is mainly composed of the carrier body formed as a solid body, whose one side is the light entering surfaces (1) of the photovoltaic devices (20) and whose reverse side is the light exiting surface with solar cells (5) in contact therewith, as well as of the solar cells (5) and their connection means.

21. A photovoltaic apparatus (24) with several photovoltaic devices according to the preamble of claim 1 and/or according to any of the claims 1 to 13,
characterized in that
all or at least a group of the solar cells (5) of the photovoltaic apparatus (24) are embedded together in a conducting plate (7) or in a conducting foil and electrically connected with this.

22. The photovoltaic apparatus according to claim 21,
characterized in that
conducting paths (10) for contacting the solar cells (5) of the photovoltaic devices (20) are applied on the transparent carrier body (6) by application of material, especially printing or sputtering or applied by masks or photo technique.

23. A method for manufacturing a photovoltaic apparatus (24) comprising a plurality of photovoltaic devices (20) for directly converting solar energy into electrical energy, each of the photovoltaic devices (20) having at least one solar cell (5) with a smaller surface area than a respective light entering surface (1) of the photovoltaic device (20) and an optical unit (2, 4) for concentrating the solar radiation (3) passing through the light entering surface on a given area defined by the smaller surface of the solar cell (5), positioned spaced apart from the light entering surface (1) and having a smaller surface in comparison to the light entering surface, wherein the solar cells (5) are commonly arranged on a transparent carrier body (6),
characterized by the following order of steps:
a1) providing a side (34) of the transparent carrier body (6) with conducting paths (10) for contacting the solar cells (5),
b1) assembling the solar cells (5) on the side (34) of the carrier body (6) provided with conducting paths (10), and
e1) arranging a heat conducting unit (8) on the side of the carrier body (6) which is turned away from the solar cells (5).

24. A method for manufacturing a photovoltaic apparatus (24) comprising a plurality of photovoltaic devices (20) for directly converting solar energy into electrical energy, each photovoltaic device (20) having at least one solar cell (5) with a smaller surface area than a respective light entering surface (1) of the photovoltaic device (20) and an optical unit (2, 4) for concentrating the solar radiation (3) passing through the light entering surface on a given area defined by the smaller surface of the solar cell (5), positioned spaced apart from the light entering surface (1) and having a smaller surface in comparison to the light entering surface, wherein the solar cells (5) are commonly arranged on a transparent carrier body (6),
characterized by the following order of steps:
a2) providing a conducting plate (7) or a conducting foil with prefabricated conducting paths for contacting the solar cells (5),
b2) assembling the conducting plate (7), the conducting foil or one side (34) of the carrier body with the solar cells (5),
e2) arranging the conducting plate (7) or the conducting foil on the side (34) of the carrier body (6) which is provided or to be provided with the solar cells.

25. The method according to claim 24,
characterized by the following step to be carried out before or after the step d2):
f) applying a heat conducting unit (8) on the conducting plate (7) or the conducting foil.

26. The method according to any of the preceding claims,
characterized by the following step to be carried out before the step e1) or e2):
d) applying a transparent fluid, preferably hardening material (9), on the side (34) of the carrier body (6) which is provided or to be provided with the solar cells (5) for protectively covering of the solar cells (5).

27. The method according to any of the preceding claims,
characterized by the following step to be carried out between the steps b1) and b2) on the one hand and e1) and e2) on the other hand:
c) testing the assembled and connected solar cells (5) by applying a voltage to the conducting paths.
